(19) United States
(12) Patent Application Publication
(10) Pub. No.: US 2001/0039101 A1
(43) Pub. Date: Nov. 8, 2001

(54) Method for converting a reclaim wafer into a semiconductor wafer

(75) Inventor: Guido Wenski, Burghausen (DE)

Correspondence Address: COLLARD & ROE, P.C., 1077 Northern Boulevard, Roslyn, NY, 11576, US

(73) Assignee: WACKER SILTRONIC GESELLSCHAFT FUR HALBLEITERMATERIALIEN AG

(21) Appl. No.: 09/791,327

(22) Filed: Feb. 23, 2001

(30) Foreign Application Priority Data
Apr. 13, 2000 (DE) 100 18 339.5
May 31, 2000 (DE) 100 27 103.0

(51) Int. Cl. H01L 21/322

(52) U.S. Cl. 438/471

(57) ABSTRACT

A method to convert a reclaim wafer into a semiconductor wafer, suitable as starting material for semiconductor fabrication, with a front surface, a back surface and an edge. At least one of the two surfaces bearing foreign material which originates from at least one process for the fabrication of semiconductor components. The method includes the following individual steps:

(a) material-removing machining of at least one foreign-material-bearing surface of the reclaim wafer;

(b) removal of surface material from at least one of the surfaces and/or the edge of the reclaim wafer by means of at least one etching step;

(c) polishing of the edge of the reclaim wafer;

(d) simultaneous polishing of the surfaces of the reclaim wafer between rotating polishing plates;

(e) single-side polishing of at least one surface of the reclaim wafer on a polishing plate.

### BACKGROUND OF THE INVENTION

1. Field of the Invention

The present invention relates to a method for converting a semiconductor wafer which is known as a reclaim wafer into a semiconductor wafer which is suitable as starting material for semiconductor fabrication, in particular for the fabrication of electronic devices with line widths of less than or equal to 0.13 μm.

2. The Prior Art

The production of integrated semiconductor devices requires semiconductor wafers which, depending on the field of use, have to satisfy certain quality demands. Areas of use include, for example, the fabrication of data processor or data storage devices for certain technology generations. Another area of use is as test wafers, also known as monitor wafers, for monitoring the processes for the fabrication of devices of this type. Examples of quality parameters include the local flatness, expressed as SFQRₘₐₓ for the worst partial region of the semiconductor wafer, and the absence of visible scratches and spots on the wafer surface. Other examples of quality parameters include the number of localized light scatterers (LLS) and the surface roughness value (haze) on the wafer surface which has been polished until it is free of streaks, generally the front surface, on which the semiconductor components are to be fabricated. Furthermore, semiconductor wafers for modern device generations, for example with line widths of 0.13 μm and below, are generally required to have a polished back surface and a polished edge.

On account of the large number of process steps required for their preparation, semiconductor wafers which are suitable for device fabrication have a high value. The price of this material may amount to up to 10% of the costs of a fully functioning device. On the other hand, large numbers of semiconductor wafers which have either been used as monitor wafers from the outset or are withdrawn from further processing on account of defects, are continuously sorted and removed during device fabrication. In the most simple case, reclaim wafers of this type have surface imperfections or defects which can be eliminated relatively easily by further cleaning or repolishing. However, by far the majority of wafers of this type are afflicted with foreign material from the device building processes which cannot be removed at acceptable cost and without quality losses using the abovementioned methods. Such-foreign material may be in the form of layers, layer fragments and semiconductor components which in the case of the layer fragments and the semiconductor components may generally be situated on the front surface, but in the case of the layers may also be situated on the back surface and the edge of the wafer. The group consisting of the layers and layer fragments may, for example, comprise semiconductor materials, such as epitaxially grown silicon layers, polysilicon or gallium arsenide, metals, such as aluminum, tungsten and copper, insulators and dielectrics, such as silicon dioxide (SiO₂), silicon nitride (Si₃N₄), silicon oxynitrides and phosphosilicates, and organics, such as polymers. The group consisting of the semiconductor components may comprise implants and diffusion regions, for example boron-, phosphorus-, arsenic- or antimony-doped silicon. These locally very restricted regions, unlike the layers and layer fragments, may extend into the semiconductor material of the wafer up to a depth of a few μm. The foreign materials described especially on the front surface of the semiconductor wafer are generally stacked in a plurality of layers.

The high potential cost saving has led to the development of methods for treating reclaim wafers afflicted with foreign material, so that these wafers can be used again in semiconductor device fabrication. According to the prior art, it is possible for foreign-material layers to be removed initially by etching. By way of example, SiO₂ can be removed using hydrofluoric acid, Si₃N₄ can be removed using hot concentrated phosphoric acid, polycrystalline and single-crystalline silicon can be removed using a hydrofluoric acid/nitric acid/acetic acid mixture or hot concentrated caustic potash solution (KOH) and organic coatings can be removed using hot, concentrated sulphuric acid. These strong acids and bases are used in aqueous solution. Semiconductor components generally remain on the front surface of the semiconductor wafer after the etching.

U.S. Pat. No. 3,559,281 describes the method of applying a passivation layer, for example of SiO₂, to the originally epitaxially grown wafer following the etching, removing this layer from the back surface, polishing the back surface and using it as the front surface for the renewed application of an epitaxial layer and of semiconductor components. One drawback of the method is that as a result of semiconductor components being covered with the passivation layer, contamination remains in the semiconductor wafer, which in modern component processes leads to problems.

In U.S. Pat. No. 3,923,567 it is proposed for phosphorus diffusion to be carried out after the etching in order to produce getter centers, for the wafer to be etched again and ground on its back surface and then for the front surface to be polished and used for the renewed application of semiconductor components. One drawback of this process is that relatively high levels of material abrasion are required in order to remove the getter centers and to ensure that the semiconductor wafer is plane-parallel.

To treat semiconductor wafers which are coated with foreign material, U.S. Pat. No. 5,131,979 describes the sequence of steps of layer removal by etching or grinding, edge-grinding, one- or two-stage polishing of the front surface, redistribution of oxidation-induced stacking faults (OSF) and application of an epitaxial layer. One drawback of this process is that relatively high reworking costs are involved.

According to JP-07122532, a semiconductor wafer which is only covered with a polysilicon film and an SiO₂ film, with a view to reuse, can initially have polysilicon removed using a hot KOH solution and can then have SiO₂ removed using a hydrofluoric acid/hydrochloric acid solution and can then be polished until it is free of streaks on the surface to which components are subsequently to be applied and can be cleaned. The treatment of SOI (silicon-on-insulator) wafers using the process sequence of etching or polishing off the single-crystalline silicon layer and, if appropriate, foreign-material layers and removing the insulating layer using hydrofluoric acid is described in EP 933 810 A1. Further steps such as a heat treatment in a reducing atmosphere and/or a polishing step may follow. One drawback of both these methods is that they cannot be used to treat semiconductor wafers which have components on them.

A preferred embodiment of U.S. Pat. No. 5,622,875 is the process sequence of etching off the foreign material layers—front-surface grinding to remove the electronic components—back-surface grinding—etching—single-side surface polishing to produce a back surface which has been polished until it is free of streaks. This back surface is defined as a new front surface when the semiconductor wafer is reused in component fabrication.

A preferred embodiment of U.S. 5,855,735 is the process sequence of rough-edge polishing to remove edge coatings two-side rough polishing in lapping mode with a concentration of abrasive substances in the polishing abrasive of greater than 6% by volume for the purpose of removing semiconductor components and coatings. Etching and single-side surface polishing are carried out for producing a front or back surface which has been polished until it is free of streaks. One drawback of both these methods is that they do not allow the preparation of a treated semiconductor wafer with one surface which has been polished until it is free of streaks, one polished surface and one polished edge.

A significant drawback of all the methods described is that they do not lead to the local flatnesses which are required for modern device processes, for example expressed as SFQRₘₐₓ less than or equal to 0.13 μm for the fabrication of electronic components with line widths of 0.13 μm.

Methods for the surface-grinding of semiconductor wafers are described, for example, in EP 272 531 A1 and EP 580 162 A1. Lapping processes for semiconductor wafers are known, for example, from DE 197 55 705 A1 and WO 97/28925. A wet chemical etching method is described, for example, in DE 198 33 257 C1. Edge-polishing methods are known, for example, from U.S. Pat. No. 5,866,477 and EP 687 524 B1. The double-side polishing of semiconductor wafers is described for example, in U.S. Pat. No. 3,691,694, EP 208 315 B1 and the German patent applications which bear the reference numbers DE 199 05 737.0 and DE 199 56 250.4. A single-side polishing method for producing a streak free surface is described, for example, in the German patent application which bears the reference number DE-10012840.8. A method for producing a semiconductor wafer with a front surface which has been polished until it is free of streaks, a polished back surface and a polished edge which satisfies the requirements imposed on semiconductor wafers for the fabrication of electronic components with line widths of 0.13 μm is claimed in the German patent application bearing the reference number DE-10004578.2.

### SUMMARY OF THE INVENTION

It is an object of the present invention to provide a method for treating a reclaim wafer which is afflicted with foreign material from processes for the fabrication of electronic devices and which after the treatment, which involves a thickness reduction of less than or equal to 50 μm, is suitable for reuse as starting material for devices with line widths of less than or equal to 0.13 μm and is superior to the known methods of the prior art in terms of yields and production costs.

The above object is achieved according to the present invention by providing a method for converting a semiconductor wafer which is known as a reclaim wafer into a semiconductor wafer which is suitable as starting material for semiconductor device fabrication, the reclaim wafer having a front surface, a back surface and an edge and, on at least one of the two surfaces, bearing foreign material which originates from at least one process for the fabrication of semiconductor components, and the method comprising the following individual steps:

(a) material-removing machining of at least one foreign-material-bearing surface of the reclaim wafer;

(b) abrasion of surface material from at least one of the surfaces and/or the edge of the reclaim wafer by means of at least one etching step;

(c) polishing of the edge of the reclaim wafer;

(d) simultaneous polishing of the surfaces of the reclaim wafer between rotating polishing plates, which are covered with polishing cloth, while a polishing abrasive with a solids concentration of from 0.1% to 5% by weight and a pH of from 9 to 12 is being supplied, the reclaim wafer lying in a cutout in a carrier; and

(e) single-side polishing of at least one surface of the reclaim wafer on a polishing plate, which is covered with polishing cloth, while a polishing abrasive with a solids concentration of from 0.1% to 5% by weight and a pH of from 9 to 12 is being supplied, a haze-free polished surface being produced.

A significant feature of the invention is that the method produces semiconductor wafers with one surface which has been polished until it is free of streaks, one polished surface and one polished edge which satisfy the requirements for reuse for the fabrication of electronic devices belonging to the 0.13-μm technology generation. The fact that the process sequence according to the invention provides high-quality semiconductor wafers of this type in high yields and at process costs which are similar to those of treatment methods for producing lower-quality wafers according to the prior art was unexcepted, was surprising, and was not foreseeable.

The starting material for the method is a single-crystalline semiconductor wafer which is known as a reclaim wafer. This comprises a material which is suitable for reuse, with a rounded edge which in processes for the fabrication of electronic devices has been afflicted with foreign material, in the form of layers, layer fragments and/or semiconductor components, on a front surface, a back surface and/or an edge and has been excluded from further processing.

The end product of the method of the invention is a single-crystalline semiconductor wafer with one surface which has been polished until it is free of streaks (haze), one polished surface and one polished edge. This end product can be used again for the fabrication of semiconductor devices belonging to the 0.13-μm technology generation and is at most 50 μm thinner than the semiconductor wafer originally used.

The method according to the invention may in principle be used to treat wafer-like bodies which consist of a material which is afflicted with foreign material and can be processed using the mechanical, chemical and chemical-mechanical surface-treatment methods employed. Examples of materials of this type are semiconductors, such as silicon or gallium arsenide. The method is particularly suitable for treating single-crystalline wafers which are afflicted with foreign material and have diameters of in particular 200 mm, 300 mm, 400 mm and 450 mm and thicknesses of from 500 μm to 1000 μm. Semiconductor wafers which have been treated according to the invention may either be directly reused as starting material for the fabrication of semiconductor devices or may be used as monitor wafers for monitoring these processes. Or following the application of layers such as back-surface seals or an epitaxial coating of the wafer front surface, for example with silicon, and/or after conditioning by a heat treatment for example under a hydrogen or argon atmosphere, these wafers may-be used for their intended purpose. Reuse in the form of SOI wafers is also possible.

The multistage method according to the invention is described in more detail on the basis of the example of the treatment of a silicon wafer as reclaim wafer in accordance with process steps (a) to (e).

(a) Surface Machining

In the context of the invention, the silicon wafer which is to be treated is initially subjected to a surface-machining step. During this step, material may in principle be abraded from the front surface and/or the back surface. Examples of suitable surface machining processes are grinding, milling and lapping methods. In the context of the invention, it is preferable to carry out a grinding or lapping method. It is particularly preferable to use a grinding method on that surface, generally the front surface, which in addition to layers and layer fragments, which are generally arranged on top of one another, also bears parts of components, such as highly doped implant and diffusion regions which, unlike the layers and layer fragments, may project into the single-crystalline silicon to a depth of a few μm. If the opposite wafer surface, generally the back surface, is afflicted with a multilayer structure comprising, for example, three or more layers or, in exceptional cases, also with parts of components, it is preferable for this surface also to be ground or for a two-sided lapping method to be employed.

Single-side grinding of the silicon wafer is carried out by means of a surface-grinding step, particularly preferably in a rotary grinding machine, with the aid of a grinding wheel which comprises metal-, resin- or ceramic-bonded diamonds with a grain coarseness of 400 mesh (grain size range 30-50 μm) to 2000 mesh (grain size range 4-6 μm). The use of a grinding wheel made from resin-bonded diamonds is particularly preferred. If it is necessary to grind both surfaces, the latter may be ground or lapped either sequentially or simultaneously; sequential surface grinding is particularly preferred in this case. It is particularly preferable for the grinding step to be carried out in such a manner that foreign material arranged in layers or layer fragments is completely removed from the ground surface(s) of the silicon wafer and from 1 to 6 μm of single-crystalline silicon is abraded from each ground wafer surface.

(b) Etching

For the purpose of removing layers on an unground surface and the edge of the silicon wafer, as well as damage and in particular metallic impurities, a single-stage or multistage etching step takes place at this location. This etching step may be carried out either as a wet chemical treatment of the silicon wafer in one or more alkaline and/or acid etching mixtures and/or as a plasma treatment. Wet chemical etching by treatment of the entire wafer surface, for example in a batch process, or only one surface of a single silicon wafer, if appropriate including the edge, for example with the aid of a so-called spin etcher is preferred. Installations are commercially available for both methods. If a multistage etching method is required, the individual stages may be carried out either in separate etching installations or in an integrated installation with a plurality of etching tanks. The number, sequence and selection of the chemicals and process conditions of the individual etching stages preferably depend on the condition of the starting material. In certain cases, in particular after two-side grinding in step (a), it may be sufficient for only the edge of the silicon wafer to be etched.

The prior art proposes various etching mixtures for the removal of various foreign materials, and all these mixtures are preferable within the context of the invention if their use is justified in view of the material which is present. Aqueous hydrofluoric acid (HF), aqueous hydrofluoric acid buffered with ammonium fluoride (BHF) or a mixture of aqueous hydrofluoric acid and hydrochloric acid in a temperature range from 20 to 60° C. and a concentration of from 0.1% to 10% by weight are suitable for SiO₂ layers. Hot, concentrated phosphoric acid (H₃PO₄ in aqueous solution) in a concentration of from 40% to 95% by weight at a temperature of from 40 to 190° C. is advantageously used for nitride-containing layers, for example Si₃N₄ or silicon oxynitrides. Under certain circumstances, HF or BHF may also be used to remove these substances. Concentrated sulphuric acid (60% to 98% by weight H₂SO₄ in aqueous solution) is suitable for the removal of organic materials, for example polymers, which have been used as photomasks during the fabrication of semiconductor structures. Polysilicon and single-crystalline silicon can be etched off by acid mixtures based on concentrated nitric acid and concentrated hydrofluoric acid at temperatures from 20° to 60° C., for example with the addition of acetic acid or acid-resistant surfactants, or in strong alkaline solutions, for example aqueous caustic soda lye (NaOH), caustic potash solution (KOH) or tetramethylammonium hydroxide solution (TMAH) at temperatures of from 40° to 120° C. In various cases, it is also possible to use plasma etching methods under attack from neutral molecules or ions in the context of the invention.

Step (b) is preferably carried out in such a way that initially all the foreign material which is still present on the silicon wafer is removed by means of one or more etching mixtures. In a particularly preferred procedure, the final etching stage removes single-crystalline silicon from the wafer, in order to remove damage and contamination caused by the grinding step (a). The amount of single-crystalline silicon removed in the etching step (b) is particularly preferably from 5 to 10 μm on each etched wafer surface.

(c) Edge-Polishing

Commercially available machines are also available for carrying out the edge-polishing step (c). Preferably, the edge of the silicon wafer is polished after the etching step (b) either using a polishing cloth which has embedded finely particulate abrasive substances. Or it is possible to use a polishing cloth without constituents of this type while an aqueous polishing abrasive which contains suspensions or colloids of a multiplicity of abrasive inorganic substances in the presence of alkaline substances and, if appropriate, further additives is supplied continuously. Examples of abrasive substances which are suitable for the edge-polishing are SiO₂, Al₂O₃, ZrO₂ and SiC. Polishing is particularly preferably carried out while a polishing abrasive comprising 1% to 5% by weight SiO₂ in water with a pH of from 10 to 12 is being supplied using a polyurethane polishing cloth with a hardness of from 30 to 70 (Shore A), which may contain reinforcing polyester fibers. The amount of single-crystalline silicon abraded, based on the surface of an edge, in step (c), is particularly preferably from 0.1 to 5 μm.

(d) Double-side Polishing

In the next step (d), a commercially available double-side polishing machine, substantially comprising a lower polishing plate which can rotate freely in the horizontal plane and an upper polishing plate which can rotate freely in the horizontal plane, both of which are covered with in each case one polishing cloth, is used. This machine allows the two-sided abrasive polishing of preferably a plurality of silicon wafers when a polishing abrasive of suitable chemical composition is continuously supplied. Polishing is particularly preferably carried out using an adhesively bonded polyurethane polishing cloth with a hardness of from 60 to 90 (Shore A) which, if appropriate, may have incorporated reinforcing polyester fibers, with a polishing abrasive comprising 1% to 5% by weight SiO₂ in water which, by the addition of potassium carbonate, has been set to a pH of from 10 to 11.5, being supplied.

During the polishing, the silicon wafers are held on a cycloid path by carriers which have adequately dimensioned cutouts for holding the silicon wafers. Carriers made from stainless chromium steel are particularly preferred, on account of their high dimensional stability and chemical resistance. To prevent damage to the wafer edge by the inner edge of the cutout in the carrier during the polishing, it is preferable for the inner side of the cutouts to be lined with a plastic coating, for example of polyamide, of the same thickness as the carrier.

In order, after step (d), to have silicon wafers with a high local flatness, a double-side polishing method as described in DE 199 05 737.0 is particularly preferred, in which method the selected thickness of the carriers depends on the final thickness of the silicon wafers following the double-side polishing step (d). The characteristic feature of this variant embodiment is that the final thickness of the double-side-polished silicon wafers is preferably 2 μm to 20 μm greater than the carrier thickness. The total amount of single-crystalline silicon which is particularly preferably abraded is from 5 to 20 μm.

To end the double-side polishing step (d), the hydrophobic wafer surface, which is very chemically reactive, has to be passivated. In the context of the invention, this preferably takes place by supplying a liquid or a plurality of liquids in succession, which contain one or more film-forming substances, leading to complete wetting of polished front surface, back surface and edge of the silicon wafers with a film of liquid, a concentration range of between 0.01 and 10% by volume of film-forming substance generally being appropriate in the stopping agent. The use of a substance which can be removed in a subsequent cleaning operation or a plurality of substances selected from a group of compounds consisting of monohydric or polyhydric alcohols, polyalcohols and surfactants, is particularly preferred within the context of the invention. An embodiment of the stopping operation which uses the same principle and is likewise particularly preferred is to supply an aqueous SiO₂-based polishing abrasive which contains one or more substances selected from the abovementioned groups of compounds in proportions of from 0.01% to 10% by volume. After the supply of stopping agent and, if appropriate, ultrapure water has been terminated, the silicon wafers are preferably removed from the polishing machine with the aid of a vacuum nozzle and are cleaned and dried in accordance with the prior art.

(e) Surface Polishing

To carry out the polishing step (e) in order to provide a front surface which has been polished until it is free of streaks, it is possible to use a commercially available surface-polishing machine with one or more polishing plates. Either one individual silicon wafer or a plurality of silicon wafers can be polished simultaneously in a polishing operation; both procedures are equally preferred. Within the context of the invention, wax-free processes for holding the semiconductor wafers during the surface polishing are preferred. It is particularly preferable for one or more silicon wafers to be held by-the application of vacuum and/or by water-assisted adhesion, by a rigid support plate which is covered with an elastic, porous film. The elastic film, which is used for contact with the wafer back surface, is preferably made from polymer foam, particularly preferably from polyurethane. The use of a support device which, instead of the rigid support plate, has an elastic membrane which, if appropriate, bears a protective layer, in step (e) is also particularly preferred within the context of the invention.

During the surface polishing (e), it is possible, within the scope of the invention, for either the front surface or the back surface of the silicon wafers to be polished until free of streaks. It is also possible for both sides to be polished until free of streaks, preferably in succession. If the starting material in step (a) has only been ground on the front surface, it is particularly preferable for step (e) to be applied to the back surface of the silicon wafer, which is thus defined, within the context of the reuse of the wafer in semiconductor component fabrication, as a new front surface.

The surface polishing (e) is preferably carried out using an adhesively bonded, soft polishing cloth with the continuous supply of an aqueous, alkaline SiO₂-based polishing abrasive with a solids content of from 0.1% to 5% by weight and a pH which is set to 9.5 to 12, if appropriate by means of additives. However, it is also possible for two different polishing abrasives to be supplied in succession, in which case the first polishing abrasive is used in a concentration of preferably between 1% and 5% by weight SiO₂ and predominantly abrades semiconductor material. The second polishing abrasive is used in a concentration of preferably between 0.1% and 2% by weight SiO₂ and predominantly smooths the surface. The two polishing abrasives may be fed successively onto a polishing plate covered with polishing cloth. It is preferable to use two different polishing abrasives in the form of a two-plate process, in that polishing is initially carried out on plate 1 using polishing abrasive 1. Then the action of the polishing abrasive is stopped, for example by supplying an aqueous citric acid solution with a concentration of between 0.1% and 20% by weight. And then polishing is carried out on plate 2 using polishing abrasive 2 and once again a stopping agent is supplied, which, as described under step (d), preferably contains, for example, a film-forming substance. The two polishing plates may in this case have different types of polishing cloths attached to-them. The amount of silicon abraded is particularly preferably between 0.1 and 1 μm. There then follows cleaning and drying of the silicon wafers according to the prior art, which may be carried out in the form of batch and/or single-wafer methods.

There follows an assessment of the silicon wafers which have been treated in accordance with steps (a) to (e) with regard to quality features which have been specified by the further processor of the wafers, using methods which are known to the person skilled in the art. Suitable assessment methods include, for example, measurement of the local geometry, a visual inspection for scratches, spots and other deviations from the ideal surface which are visible under neon light or strongly focused light (haze light). There is also possibly an inspection by instruments of preferably that surface of the silicon wafers which has been polished until it is free of streaks, with the aid of a commercially available laser detection unit with regard to LLS numbers for scatterers of various size classes and haze.

If necessary, a heat treatment of the silicon wafers may be incorporated at a suitable point in the process sequence, for example in order to destroy thermal donors, in order to anneal out damage to crystal layers close to the surface or in order to bring about controlled dopant depletion in the latter layers. Furthermore, laser marking in order to identify the wafers may be produced. The application of an epitaxial layer of silicon or further semiconductive materials on that surface of the silicon wafers which has been polished until it is free of streaks, as is advantageous in various applications, is also possible.

Semiconductor wafers, in particular silicon wafers, which have been treated in accordance with the invention satisfy the requirements imposed for the fabrication of semiconductor components with line widths of less than or equal to 0.13 μm if the crystal material of the semiconductor wafer which was originally used, was sorted out after becoming afflicted with foreign material and has been treated is suitable for such a purpose. In particular, it is not obvious that the method according to the invention allows the provision of semiconductor wafers with one surface which has been polished until it is free of streaks, one polished surface and one polished edge and a local geometry SFQRₘₐₓ of less than or equal to 0.13 μm even if the semiconductor wafer originally used did not have-these properties. With typical yields of 85 to 95% of wafers which are suitable for the 0.13-μm technology, this method has proven to be the optimum solution for lowering materials costs in semiconductor component fabrication. The application of cost calculation models demonstrates that the treatment method according to the invention for semiconductor wafers is comparable to the methods according to the prior art, but produces a higher quality product.

### BRIEF DESCRIPTION OF THE DRAWINGS

Other objects and features of the present invention will become apparent from the following detailed description considered in connection with the accompanying drawing which discloses several embodiments of the present invention. It should be understood, however, that the drawing is designed for the purpose of illustration only and not as a definition of the limits of the invention.

Figures which explain the invention without restricting it are associated with the description and the cited example.

FIG. 1 shows a process sequence for the treatment of a coated semiconductor wafer according to the prior art which leads to a semiconductor wafer with one surface which has been polished until it is free of streaks, one etched surface and one etched edge;

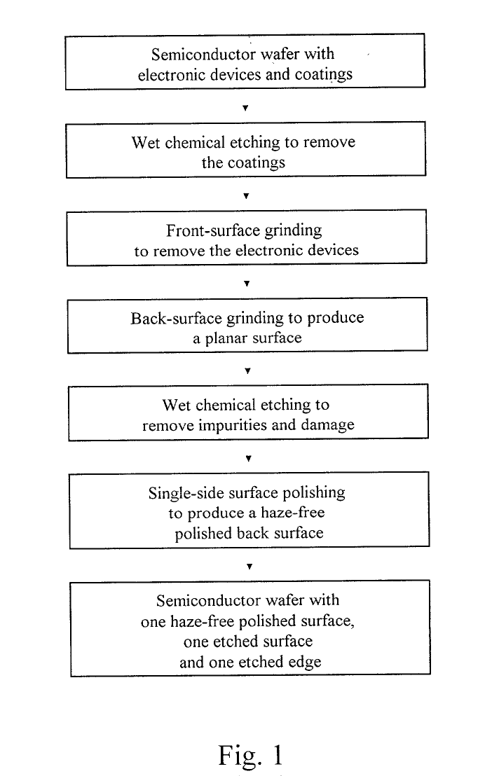

FIG. 2 shows a further process sequence for the treatment of a coated semiconductor wafer according to the prior art which leads to a semiconductor wafer with one surface which has been polished until it is free of streaks, surface which has been polished until it is free of streaks, one etched surface and one etched edge; and

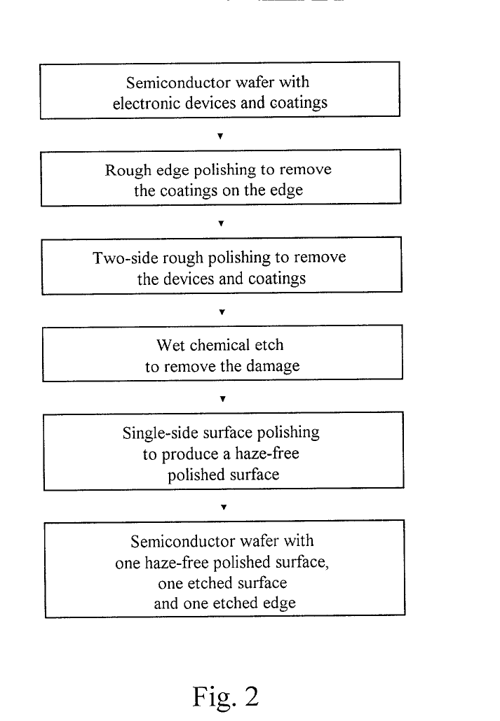

FIG. 3 shows a preferred process sequence according to the invention for treating a coated semiconductor wafer which leads to a semiconductor wafer having one surface which has been polished until it is free of streaks, one polished surface and one polished edge and was produced using the example described.

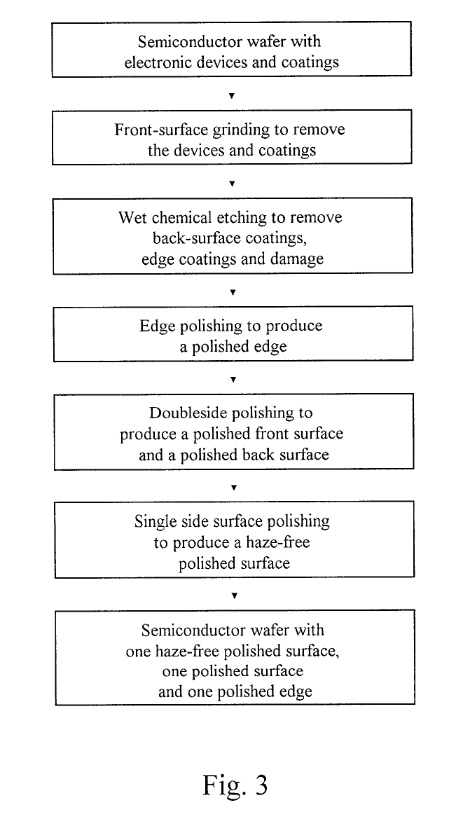

### DETAILED DESCRIPTION OF PREFERRED EMBODIMENTS

### EXAMPLE

Weakly boron-doped silicon wafers (resistance 10-20 Ω·cm; diameter 300 mm) were provided, which had been supplied with a front surface polished until free of steaks, a polished back surface, a polished edge and a thickness of 775 μm, for semiconductor component fabrication in accordance with the 0.13-μm technology generation and had been rejected for quality reasons. The wafers were afflicted with foreign material as follows: the front surface was covered with diffusion regions (silicon, doped with boron and/or phosphorus) and layers and layer fragments (SiO₂, Si₃N₄, polysilicon and aluminum). The edge and the back surface were covered with SiO₂.

(a) Surface Grinding of the Front Surface

The front surface of the semiconductor wafers was machined by means of a surface-grinding step on a rotary grinding machine, a resin-bonded grinding wheel with diamonds with a grain coarseness of 600 mesh (grain size range 20-30 μm) being used. The amount of material abraded by grinding was such that all the foreign material, including the diffusion regions, was removed from the front surface, 5 μm of the silicon wafer being ground off in addition to the foreign materials.

(b) Wet Chemical Etching

In order to remove the SiO₂ coating on the edge and back surface, in each case 26 silicon wafers in an etching magazine made from polyvinylidene difluoride (PVDF) were dipped into an aqueous hydrofluoric acid solution (1% by weight), the temperature of which was controlled at 50° C., in an integrated etching installation. After complete removal of the SiO₂ layer, without any significant abrasion of the silicon wafer, the wafers were lifted, in dry and hydrophobic form, into an ozone-filled gas chamber and were thus uniformly rendered hydrophilic. This was immediately followed by an acid etching step using the flow etching method, with 5 μm of silicon being simultaneously from each wafer surface as a result of the rotating wafers being dipped in a mixture, the temperature of which was controlled at 20° C., of 90% by weight concentrated nitric acid (70% by weight in aqueous solution), 10% by weight concentrated hydrofluoric acid (50% by weight in aqueous solution) and 0.1% by weight ammonium lauryl sulfate. After the set of wafers had been transferred into a quickdump rinse which was filled a total of 3 times with ultrapure water, the wafers were dried in a drier which likewise operates according to the hydrofluoric acid/ozone principle; the temperature of the 0.5% strength by weight aqueous hydrofluoric acid solution was 20° C.

(c) Edge-polishing

The edges of the wafers which had been ground and etched as described in steps (a) and (b) were polished on an edge-polishing installation for 300-mm wafers using an aqueous polishing abrasive of type Levasil 200 produced by Bayer, with an SiO₂ solids content of 3% by weight and a pH which was set at 10.5 by the addition of potassium carbonate, a polyurethane polishing cloth which was reinforced with polyester fibers and had a hardness of 50 (Shore A) being used. In the process, firstly the lower flank of the wafer edge and then the upper flank of the wafer edge were successively polished by rotation of the silicon wafer using an angled polishing plate covered with polishing cloth.

(d) Double-side Polishing

The thickness of the silicon wafers supplied to the double-side polishing step (d) was 760 μm. Five carriers made from stainless chromium steel with a thickness of 740 μm, which each had three circular cutouts arranged at regular intervals on a circular path, lined with polyamide and with an internal diameter of 301 mm and allowed the simultaneous polishing of 15 300-mm silicon wafers, were available for the double-side polishing. Polishing was carried out using a commercially available polishing cloth made from porous polyurethane foam of-hardness 80 (Shore A), which was in each case adhesively bonded on the upper and lower polishing plate, using an aqueous polishing abrasive of type Levasil 200, produced by Bayer, with an SiO₂ solids content of 3% by weight and a pH which was set at 10.5 by the addition of potassium carbonate, under a pressure of 0.15 bar. The polishing took place with the upper and lower polishing plates each at a temperature of 40° C., leading to an abrasion of 0.63 μm/min.

The supply of the polishing abrasive was terminated after the thickness of the polished wafers reached 745 μm, corresponding to 15 μm of abraded silicon, and, in order to stop the polishing process, was replaced by the sequential supply of the liquids listed below, while maintaining rotary conditions: (1) 2% strength by weight mixture of the polishing abrasive Glanzox 3900 produced by Fujimi with ultrapure water (3 min; 0.05 bar); (2) ultrapure water (2 min; 0.03 bar); (3) aqueous solution of 1% by volume glycerol, 1% by volume n-butanol and 0.07% by volume of the surfactant Silapur (alkylbenzenesulfonic acid and amine ethoxylate, produced by ICB; 2 min; 0.03 bar). After the upper polishing plate had been raised and pivoted away, the front surfaces of the finish-polished silicon wafers positioned in the carrier cutouts were completely wetted with stopping liquid.

A vacuum nozzle which was provided with a handle, consisted of polypropylene and had three suction cups made from soft PVC was available for removing the silicon wafers from the double-side polishing machine. Moreover, a commercially available 300-mm wet tray filler for receiving the polished silicon wafers was available and filled with ultrapure water. The procedure was that the carriers were left in position during the removal of the wafers and the wafers were removed and transferred into the wet tray filler individually with the aid of the vacuum nozzle. The silicon wafers were then cleaned and dried using the batch method known from the prior art.

Surface Polishing (e)

A surface-polishing step (e) for producing a polished surface free of streaks was carried out on the back surface of the silicon wafers, i.e. that surface which was not afflicted with diffusion regions before steps (a) to (d) were carried out. As a result of this procedure, the original back surface was defined as the new front surface of the wafers. For step (e), a single-wafer polishing machine with two separate polishing plates and a rotating support device for semiconductor wafers with a diameter of 300 mm, which was substantially composed of a rigid support plate to which an elastic polyurethane film was adhesively bonded and a lateral boundary ring, which was likewise stuck on, was available. After the baseplate had been screwed on, the support device was secured to the polishing spindle of the installation.

A two-stage polishing process was carried out, during which the new front surface of the silicon wafers was firstly polished on plate 1 and, after a brief intermediate cleaning operation in ultrapure water had been carried out, was immediately afterward polished on plate 2. This was followed by cleaning and drying initially in a single-wafer process and then in a batch method. On plate 1, polishing was carried out using a Polytex polishing cloth produced by Rodel with the addition of the polishing. Levasil 300 (3% by weight SiO₂ in ultrapure water; pH set at 10.5 by the addition of K₂CO₃) for a period of 3 min. Then, to stop the polishing operation, a solution of 10% by weight citric acid in ultrapure water was supplied for a period of 20 sec, and ultrapure water without additives was supplied for a further 15 sec, while the polishing plate and spindle continued to rotate. Plate 2 was covered with a polishing cloth of type Napcon 4500 N2 produced by Nagase. To carry out the second, smoothing polishing step, the polishing Glanzox 3900 (1% by weight SiO₂ in ultrapure water; pH 9.8) was supplied for a period of 2 min, followed by ultrapure water being supplied for a period of 30 sec while polishing plate and spindle continued to rotate. The total amount of silicon abraded from the front surface of the semiconductor wafer was 0.6 μm. The wafers treated in this way had a thickness of 744 μm; the total amount of silicon abraded was therefore 31 μm.

According to a geometry measurement carried out on an apparatus operating using the capacitive measurement principle, the silicon wafers which had been processed as described in steps (a) to (e) had a flatness SFQRₘₐₓ of (0.11±0.02) μm. There followed a visual assessment of the front and back surfaces of the silicon wafers under haze light in a darkened assessment chamber, to check for scratches and spots, and then an instrument was used for surface assessment of the new front surface, which had been polished until free of streaks, on a laser surface-inspection unit of type SP1 produced by KLA Tencor, to check for haze and number of LLS with a diameter of greater than or equal to 0.12 μm, in each case in the DNN channel. It was found that after step (e), 92% —based on the number of wafers used in step (a)—of the silicon wafers satisfy the specifications imposed for component processes involved in the 0.13-μm technology generation. This means that there were no scratches and spots on front and back surface, haze of less than or equal to 0.065 ppm and at most 100 LLS of greater than or equal to 0.12 μm on the new front surface. Therefore these wafers were suitable for reuse in semiconductor component fabrication.

Accordingly, while a few embodiments of the present invention have been shown and described, it is to be understood that many changes and modifications may be made thereunto without departing from the spirit and scope of the invention as defined in the appended claims.

What is claimed is:

1. A method for converting a semiconductor wafer which is known as a reclaim wafer into a semiconductor wafer which is suitable as starting material for semiconductor fabrication, the reclaim wafer having a front surface, a back surface and an edge between these surfaces and, on at least one of the two surfaces, bearing foreign material which originates from at least one process for the fabrication of semiconductor components, and the method comprising the following individual steps:
(a) material-removing machining of at least one foreign-material-bearing surface of the reclaim wafer;
(b) abrading of surface material selected from the group consisting of at least one of the surfaces, the edge, both a surface and the edge of the reclaim wafer by means of at least one etching step;
(c) polishing of the edge of the reclaim wafer;
(d) simultaneous polishing of the surfaces of the reclaim wafer between rotating polishing plates, which are covered with polishing cloth, while a polishing abrasive with a solids concentration of from 0.1% to 5% by weight and a pH of from 9 to 12 is being supplied, the reclaim wafer lying in a cutout in a carrier; and
(e) single-side polishing of at least one surface of the reclaim wafer on a polishing plate, which is covered with polishing cloth, while a polishing abrasive with a solids concentration of from 0.1% to 5% by weight and a pH of from 9 to 12 is being supplied, a surface which has been polished until it is free of streaks being produced.

2. The method as claimed in claim 1,
wherein the foreign material is selected from the group of materials consisting of layers, layer fragments and semiconductor components.

3. The method as claimed in claim 2,
wherein the group consisting of layers and layer fragments comprises semiconductor materials, metals, insulators, dielectrics and organics and the group consisting of semiconductor components comprises implants and diffusion regions.

4. The method as claimed in claim 1,
wherein the back surface of the reclaim wafer is free of semiconductor components.

5. The method as claimed in claim 1,
wherein step (a) is selected from the group consisting of grinding step and a lapping step.

6. The method as claimed in claim 1,
wherein step (a) is carried out as a surface-grinding step on at least the front surface of the reclaim wafer, the foreign material being completely abraded from the front surface and the back surface.

7. The method as claimed in claim 1,
wherein step (a) is carried out as a double-side grinding step, the foreign material being completely abraded from the front surface and the back surface.

8. The method as claimed in claim 6,
wherein in step (a) 1 to 6 μm of single-crystalline semiconductor material is abraded from each ground wafer surface.

9. The method as claimed in claim 1,
wherein in step (b) at least one wet chemical etching step is carried out.

10. The method as claimed in claim 9,
wherein to carry out the wet chemical etching step (b) an aqueous mixture selected from the group consisting of at least one strong acid and at least one strong base is used.

11. The method as claimed in claim 9,
wherein in step (b) 5 to 10 μm of single-crystalline semiconductor material is abraded from each etched wafer surface.

12. The method as claimed in claim 1,
wherein in step (c) polishing is carried out using a polishing cloth while a polishing abrasive with a solids concentration of from 0.1% to 5% by weight and a pH of from 9 to 12 is being supplied.

13. The method as claimed in claim 1,
wherein the aqueous polishing abrasive used in steps (c), (d) and (e) contains silicon dioxide as solid.

14. The method as claimed in claim 1, wherein in step (c) polishing is carried out using a polishing cloth which contains abrasive substances.

15. The method as claimed in claim 1,
wherein in step (d) the amount of material abraded is from 2 μm to 40 μm and the carrier used has a thickness which is 2 μm to 20 μm less than the finish-polished reclaim wafer.

16. The method as claimed in claim 1,
wherein in step (d) at least one liquid which contains at least one film-forming substance is supplied in order to stop the polishing operation.

17. The method as claimed in claim 1,
wherein step (e) is carried out as a single-stage process on a polishing plate covered with polishing cloth.

18. The method as claimed in claim 1, comprising
carrying out step (e) as a two-stage process on two separate polishing plates covered with polishing cloth.

19. The method as claimed in claim 1, comprising
abrading in step (e) from 0.1 μm to 1 μm of material.

20. The method as claimed in claim 1,
wherein in step (e) a liquid selected from the group consisting of a liquid which contains at least one film-forming substance, a liquid having a pH of from 2 to 8, and a mixture thereof, is supplied in order to stop the polishing operation.

21. The method as claimed in claim 1,
wherein the total amount of single-crystalline semiconductor material abraded after steps (a) to (e) have been carried out is from 15 μm to 50 μm.

22. The method as claimed in claim 1,
wherein after the method steps (a) to (e) have been carried out, applying a semiconductive epitaxial coating to a surface of the reclaim wafer which has been polished until it is free of streaks.

23. The method as claimed in claim 1,
wherein the reclaim wafer consists of silicon.

24. The method as claimed in claim 1,
wherein the semiconductor wafer formed from the reclaim wafer has a local flatness SFQRₘₐₓ of less than or equal to 0.13 μm, based on a component area of 25 mm×25 mm.
